(19) United States
(12) Patent Application Publication
(10) Pub. No.: US 2026/0155808 A1
(43) Pub. Date: Jun. 4, 2026

(54) PULSE WIDTH MODULATION ELECTRODE CONTROL AND CORRESPONDING METHODS

(71) Applicant: Quantinuum LLC, Broomfield, CO (US)

(72) Inventors: Leonardo Ascarrunz, Broomfield, CO (US); Brian Mathewson, Broomfield, CO (US)

(21) Appl. No.: 18/658,523

(22) Filed: May 8, 2024

Related U.S. Application Data
(60) Provisional application No. 63/502,260, filed on May 15, 2023.

(51) Int. Cl. H03K 3/013; G06N 10/40; G21K 1/20; H03H 7/06; H03K 3/017

(52) U.S. Cl. CPC H03K 3/013; G21K 1/20; H03K 3/017; G06N 10/40; H03H 7/06

(57) ABSTRACT

Embodiments of the disclosure provide for using pulse width modulation (PWM) to generate signals applied to an electrode of an ion trap while mitigating noise thereof. In some embodiments a PWM signal generator is configured to generate at least one signal, a filter network is configured to filter the at least one signal, and a controller is configured to control operation of the PWM signal generator and the filter network. The controller may cause the PWM signal generator to generate the at least one signal. The at least one signal may be provided to the filter network. The controller may cause the filter network to filter the at least one signal in accordance with a noise requirement, and the filtered at least one signal may be provided to an electrical component of the system.

### CROSS-REFERENCE TO RELATED APPLICATIONS

This application claims priority to and the benefit of U.S. Provisional Application No. 63/502,260, titled “PULSE WIDTH MODULATION ELECTRODE CONTROL AND CORRESPONDING METHODS,” filed May 15, 2023, the contents of which is incorporated by reference herein in its entirety.

### TECHNICAL FIELD

Various embodiments relate to apparatuses, systems, and methods for generating signals used in systems, such as quantum computing systems. For example, some embodiments relate to the use of pulse width modulation (PWM) to generate signals applied to an electrode of an ion trap while mitigating noise thereof.

### BACKGROUND

In various scenarios, a system having electrical components may be configured to perform multiple functions and different functions may have different tolerances. These tolerances may include the amount of the noise present in the signals that are applied to the various electrical components. For example, an ion trap can use a combination of electrical and magnetic fields to capture a plurality of ions in a potential well. Various functions may be performed to cause the ions to move in particular ways through portions of the ion trap and/or be contained in particular portion of the ion trap. These various functions may have differing tolerances in the signals used to generate the combination of electrical and magnetic fields for the electrical components. Through applied effort, ingenuity, and innovation, many deficiencies of such prior ion traps have been solved by developing solutions that are structured in accordance with embodiments of the present invention, many examples of which are describe in detail herein.

### BRIEF SUMMARY

In general, embodiments of the present disclosure herein provide for the use of pulse width modulation (PWM) to generate signals applied to an electrode of an ion trap while mitigating noise thereof.

In accordance with one aspect of the present disclosure, an example system for providing a signal to an electrical component is provided. In some embodiments, the example system includes a PWM signal generator configured to generate at least one signal; a filter network configured to filter the at least one signal; and a controller configured to control operation of the PWM signal generator and the filter network, wherein the controller causes the PWM signal generator to generate the at least one signal, the at least one signal is provided to the filter network, the controller causes the filter network to filter the at least one signal in accordance with a noise requirement, and the filtered at least one signal is provided to an electrical component of the system.

In some example embodiments, the PWM signal generator is an FPGA-based PWM signal generator.

In some example embodiments, the at least one signal is a high frequency PWM signal.

In some example embodiments, the PWM signal generator comprises a first clock, a second clock, and an XOR gate, and wherein the first clock is associated with a delay relative to the second clock.

In some example embodiments, the high frequency PWM signal is generated based at least in part on a switching frequency that is generated using the XOR gate, wherein the XOR gate is configured to perform an XOR operation on a first clock signal generated by the first clock and a second clock signal generated by the second clock.

In some example embodiments, a first signal generated by the PWM signal generator and a second signal generated by the PWM signal generator are combined to generate a PWM signal having suppressed harmonic component.

In some example embodiments, a low harmonic frequency in the at least one signal is suppressed based at least in part on a switching frequency of the at least one signal.

In some example embodiments, the filter network comprises a passive filter.

In some example embodiments, the system is a quantum computer.

In some example embodiments, the electrical component is an electrode of an ion trap having a plurality of ions trapped therein, at least some of the plurality of ions being used as qubits of the quantum computer.

In accordance with another aspect of the present disclosure, a method for providing a signal to an electrical component of a system. In some example embodiments, the method comprises causing, by a controller of the system, a PWM signal generator to generate at least one signal; and causing, by the controller of the system, a filter network to filter the at least one signal, wherein the at least one signal generated by the PWM signal generator is provided to the filter network, the filter network filters the at least one signal in accordance with a noise requirement, and the filtered at least one signal is provided to an electrical component of the system.

In some example embodiments, the PWM signal generator is an FPGA-based PWM signal generator.

In some example embodiments, the at least one signal is a high frequency PWM signal.

In some example embodiments, the PWM signal generator comprises a first clock, a second clock, and an XOR gate, and wherein the first clock is associated with a delay relative to the second clock.

In some example embodiments, the high frequency PWM signal is generated based at least in part on a switching frequency that is generated using the XOR gate, wherein the XOR gate is configured to perform an XOR operation on a first clock signal generated by the first clock and a second clock signal generated by the second clock.

In some example embodiments, the first signal generated by the PWM signal generator and a second signal generated by the PWM signal generator are combined to generate a PWM signal having suppressed harmonic component.

In some example embodiments, low frequency harmonic component of the at least one signal is suppressed based at least in part on selected switching frequency of the at least one signal.

In some example embodiments, the filter network comprises a passive filter.

In some example embodiments, the system is a quantum computer.

In accordance with another aspect of the present disclosure, a computer program product is provided, In some example embodiments, the computer program product comprises a non-transitory, machine-readable storage medium storing executable instructions that, when executed with a processor of a controller, cause the controller to: cause a PWM signal generator to generate at least one signal; and cause a filter network to filter the at least one signal, wherein the at least one signal generated by the PWM signal generator is provided to the filter network, the filter network filters the at least one signal in accordance with a noise requirement, and the filtered at least one signal is provided to an electrical component of the system.

### BRIEF DESCRIPTION OF THE SEVERAL VIEWS OF THE DRAWINGS

Having thus described the invention in general terms, reference will now be made to the accompanying drawings, which are not necessarily drawn to scale, and wherein:

FIG. 1 provides a top view of an example atomic object confinement apparatus that may be used in example embodiment.

FIG. 2 is a block diagram illustrating a system for generating a control voltage applied to an electrode of an example atomic object confinement apparatus in accordance with an example embodiment.

FIG. 3 is a schematic diagram of an example filter network in accordance with an example embodiment.

FIG. 4 is a schematic diagram illustrating an example PWM signal generator in accordance with an example embodiment.

FIG. 5 is a schematic diagram illustrating an example PWM signal generator embodying an exemplary noise mitigation circuitry in accordance with an example embodiment.

FIG. 6 provides a Fast Fourier Transform plot (FFT) plot for a PWM signal generator in accordance with an example embodiment.

FIG. 7 provides a noise spectral density plot (NSD) for a PWM signal generator in accordance with an example embodiment.

FIG. 8a is a schematic diagram illustrating an example PWM signal generator embodying another exemplary noise mitigation circuitry in accordance with an example embodiment.

FIG. 8b provides a Fast Fourier Transform (FFT) plot for a PWM signal generator in accordance with an example embodiment.

FIG. 9 is a schematic diagram illustrating an example PWM signal generator embodying another exemplary noise mitigation circuitry in accordance with an example embodiment.

FIG. 10 is a flowchart of various processes, procedures, and/or operations, and/or the like that may be performed, for example, by a controller of an atomic object confinement apparatus

FIG. 11 is a schematic diagram illustrating an example quantum computing system in accordance with an example embodiment.

FIG. 12 provides a schematic diagram of an example controller of a quantum computer in accordance with an example embodiment.

FIG. 13 provides a schematic diagram of an example computing entity of a quantum computer system that may be used in accordance with an example embodiment.

### DETAILED DESCRIPTION OF SOME EXAMPLE EMBODIMENTS

The present invention now will be described more fully hereinafter with reference to the accompanying drawings, in which some, but not all embodiments of the invention are shown. Indeed, the invention may be embodied in many different forms and should not be construed as limited to the embodiments set forth herein; rather, these embodiments are provided so that this disclosure will satisfy applicable legal requirements. The term “or” (also denoted “/”) is used herein in both the alternative and conjunctive sense, unless otherwise indicated. The terms “illustrative” and “exemplary” are used to be examples with no indication of quality level. The terms “generally” and “approximately” refer to within engineering and/or manufacturing limits and/or within user measurement capabilities, unless otherwise indicated. Like numbers refer to like elements throughout.

In various embodiments, methods, apparatuses, systems, computer program products, and/or the like for generating and providing pulse width modulated (PWM)-based signals for a system, such as a quantum computing system. For example, a signal may be generated (e.g., by a PWM signal generator) and applied to an electrical component (e.g., electrode) of a system. Application of the signal to the electrical component may cause the system to perform a function. In various embodiments, depending on the signal applied to the electrical component, the system may be configured to perform a variety of functions. In an example embodiment, different functions of the variety of functions may have different requirements regarding the amount of noise and/or frequency of noise in the applied signal that can be tolerated. In various embodiments, one or more amplifiers may be used to amplify a signal, and/or a filter network may be used to filter a signal (e.g., generated by a PWM signal generator) prior to the signal being applied to the electrical component (e.g., electrode) of the system. A filter network may include an active filter, a passive filter, or an active filter and a passive filter. An active filter is a filter that may be comprised of active components (e.g., op-amps, transistors, etc.) and have a response that is determined from these components. Additionally or alternatively, an active filter may be a dynamic filter, which may have an operating response that may be changed dynamically (e.g., during operation of the system). A passive filter is a filter using passive components (e.g., resistors, capacitors, inductors, etc.) with a response that is determined from these components.

In an example embodiment, the system is a quantum computer. For example, the system may be a trapped ion quantum computer comprising an ion trap comprising a plurality of electrodes. Application of signals (e.g., PWM control signals) to the electrodes may cause the ion trap to perform various functions corresponding to moving or maintaining atomic objects (e.g., ions, atoms, and/or the like) trapped within the ion trap. For example, the various functions may include transporting atomic objects from one location within the ion trap to another location in the ion trap, maintaining an atomic object in a particular location within the ion trap so that quantum logic gate may be performed on the atomic object, causing two atomic objects to swap positions within the ion trap, cause two atomic objects to move close together, cause two atomic objects that are close together to move apart from one another, and/or the like. Each of these functions may be associated with functions-specific tolerances (e.g., noise tolerance). Atomic objects in trapped ion quantum computers are physically moved around the traps by use of signals (e.g., waveforms) generated by a signal generator (e.g., an arbitrary waveform generator (AWG)) and applied to the electrical components (e.g., electrodes) of the trap. As such, it is desirable to efficiently and effectively generate the signals to move these ions around the trap.

### Exemplary Atomic Object Confinement Apparatus

In an example embodiment, the system is or comprises an atomic object confinement apparatus (also referred to as a confinement apparatus herein). In an example embodiment, the confinement apparatus is an ion trap (e.g., a surface ion trap). For example, the ion trap may comprise a plurality of electrodes configured to receive electrical signals (e.g., voltages) so as to generate a potential field that controls the movement of one or more atomic objects (e.g., ions) within the ion trap.

Various functions performed to control the movement of the one or more atomic objects may have different requirements. An example of a requirement may be to limit the noise in an electrical signal applied to the electrodes. For example, the noise requirements for performing a transport function, wherein an atomic object is moved from one location in the ion trap to another location in the ion trap, may be a first noise requirement and the noise requirements for maintaining an atomic object at a particular location within the ion trap (e.g., so that a gate operation of a quantum computer for which the atomic object is a qubit may be performed) may be a second noise requirement. In an example embodiment, the first noise requirement and the second noise requirement may be different. For example, when performing the transport function, performance of the function may be sensitive to noise at frequencies around 1 MHz. In another example, when performing the maintaining function (e.g., maintaining the atomic object at a particular location within the ion trap so that a quantum logic gate may be executed on the atomic object), performance of the function may be sensitive to noise at frequencies around 250 kHz. Thus, performing the transport function using the noise requirements configured to optimize performance of the maintaining function, leads to decreased performance of the transport function. For example, performing the transport function using the noise requirements configured to optimize performance of the maintaining function decreases the speed and/or bandwidth with which the transport function may be performed. In some embodiments one or more of the electrodes comprise shim electrodes.

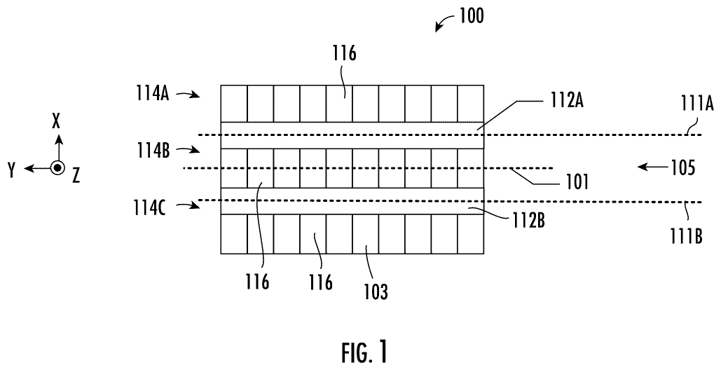

FIG. 1 provides a top schematic view of an example surface ion trap 100. In an example embodiment, the surface ion trap 100 is fabricated as part of an ion trap chip and/or part of an ion trap apparatus and/or package. In an example embodiment, the surface ion trap 100 is at least partially defined by a number of radio frequency (RF) rails 112 (e.g., 112A, 112B). In various embodiments, the ion trap 100 is at least partially defined by a number of sequences of trapping and/or transport (TT) electrodes 114 (e.g., 114A, 114B, 114C). In an example embodiment, the ion trap 100 is a surface Paul trap with symmetric RF rails. In various embodiments, the potential generating elements of the confinement apparatus comprise the TT electrodes 116 of the sequences of TT electrodes 114 and/or the RF rails 112. In various embodiments, the upper surface of the ion trap 100 has a planarized topology. For example, the upper surface of each RF rail 112 of the number of RF rails 112 and the upper surface of each TT electrode 116 of the number of sequences of TT electrodes 114 may be substantially coplanar.

In various embodiments, the ion trap 100 comprises and/or is at least partially defined by a number of RF rails 112. The RF rails 112 are formed with substantially parallel longitudinal axes 111 (e.g., 111A, 111B) and with substantially coplanar upper surfaces. For example, the RF rails 112 are substantially parallel such that a distance between the RF rails 112 is approximately constant along the length of the RF rails 112 (e.g., the length of an RF rail being along the longitudinal axes 111 of RF rail 112). For example, the upper surfaces of the RF rails 112 may be substantially flush with the upper surface of the ion trap 100. In an example embodiment, the number of RF rails 112 comprises two RF rails 112 (e.g., 112A, 112B). In various embodiments, the ion trap 100 may comprise a plurality of number of RF rails 112. For example, the ion trap 100 may be a two-dimensional ion trap that comprises multiple numbers (e.g., pairs and/or sets) of RF rails 112 with each number (e.g., pair and/or set) of RF rails 112 having substantially parallel longitudinal axes 111. In an example embodiment, a first number of RF rails 112 have mutually substantially parallel longitudinal axes 111, a second number of RF rails 112 have mutually substantially parallel longitudinal axes 111, and the longitudinal axes of the first number of RF rails and the longitudinal axes of the second number of RF rails are substantially non-parallel (e.g., transverse). FIG. 1 illustrates an example one dimensional ion trap 100 having two RF rails 112, though other embodiments may comprise additional RF rails in various configurations.

In various embodiments, two adjacent RF rails 112 may be separated (e.g., insulated) from one another by a longitudinal gap 105. For example, the longitudinal gap may define (in one or two dimensions) the confinement channel or region of the ion trap 100 in which one or more atomic objects (e.g., ions in the case of the confinement apparatus being an ion trap 100) may be trapped at various locations within the ion trap. In various embodiments, the longitudinal gap 105 defined thereby may extend substantially parallel to the longitudinal axes 111 of the adjacent RF rails 112. For example, the longitudinal gap 105 may extend substantially parallel to the y-axis. In an example embodiment, the longitudinal gap 105 may be at least partially filled with an insulating material (e.g., a dielectric material). In various embodiments, the dielectric material may be silicon dioxide (e.g., formed through thermal oxidation) and/or other dielectric and/or insulating material. In various embodiments, the longitudinal gap 105 has a height (e.g., in the x-direction) of approximately 40 μm to 500 μm. In various embodiments, one or more sequences of TT electrodes 114 (e.g., a second sequence of TT electrodes 114B) may be disposed and/or formed within the longitudinal gap 105.

In an example embodiment, a transverse gap may exist between neighboring and/or adjacent electrodes 116 of the one or more sequences of electrodes 114. In an example embodiment, the transverse gap may be empty space and/or at least partially filled with a dielectric material to prevent electrical communication between neighboring and/or adjacent electrodes. In an example embodiment, the transverse gap between neighboring and/or adjacent electrodes may be in the range of approximately 1-10 μm.

In an example embodiment, a longitudinal gap exists between a sequence of TT electrodes 114 and a neighboring and/or adjacent RF rail 112. In an example embodiment, the longitudinal gap may be at least partially filled with a dielectric and/or insulating material to prevent electrical communication between TT electrodes 116 of the sequence of electrodes 114 and the RF rail 112. In an example embodiment, the longitudinal gap between neighboring and/or adjacent electrodes may be in the range of approximately 1-10 μm.

In various embodiments, the ion trap 100 may be at least partially defined by a number of sequences of TT electrodes 114 (e.g., first sequence of TT electrodes 114A, second sequence of electrodes 114B, third sequence of TT electrodes 114C). Each sequence of TT electrodes 114 is formed to extend substantially parallel to the substantially parallel longitudinal axes 111 of the RF rails 112. For example, the number of sequences of TT electrodes 114 may extend substantially parallel to the y-axis as shown in FIG. 1. In various embodiments, the number of sequences of TT electrodes 114 comprises two, three, four, and/or another number of sequences of TT electrodes 114. In an example embodiment, the ion trap 100 comprises a plurality of number of sequences of TT electrodes 114. For example, the illustrated ion trap 100 is a one-dimensional ion trap comprising three sequences of TT electrodes 114. For example, the ion trap 100 may be a two-dimensional ion trap that comprises multiple numbers of sequences of TT electrodes 114 that each extend substantially parallel to a substantially parallel longitudinal axes of a corresponding number of RF rails 112. In an example embodiment, a first number of sequences of TT electrodes 114 extend substantially parallel to the substantially parallel longitudinal axes 111 of a first number of RF rails 112, a second number of sequences of TT electrodes 114 extend substantially parallel to the substantially parallel longitudinal axes 111 of a second number of RF rails 112, and the longitudinal axes of the first number of RF rails and the longitudinal axes of the second number of RF rails are substantially non-parallel (e.g., transverse). In some embodiments, each of the TT electrodes 116 of the number of sequences of TT electrodes 114 can be formed with substantially coplanar upper surfaces that are substantially coplanar with the upper surfaces of the RF rails 112.

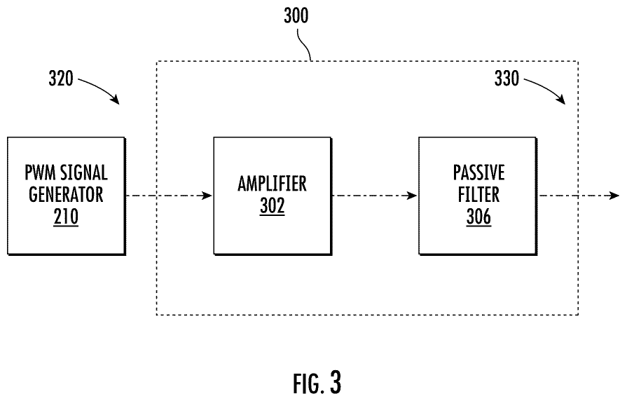

In an example embodiment (e.g., as illustrated in FIGS. 3-5), a number (e.g., pair) of RF rails 112 may be formed between a first sequence of TT electrodes 114A and a third sequence of TT electrodes 114C with a second sequence of TT electrodes 114B extending along the longitudinal channel 105 between the RF rails 112. For example, each sequence of TT electrodes 114 may extend in a direction substantially parallel to the longitudinal axes 111 of the RF rails (e.g., in the y-direction). In various embodiments, the upper surfaces of the sequences of TT electrodes 114 are substantially coplanar with the upper surfaces of the RF rails 112.

In various embodiments, RF signals may be applied to the RF rails 112 to generate an electric and/or magnetic field that acts to maintain an ion trapped within the ion trap 100 in directions transverse to the longitudinal direction of the ion trap 100 (e.g., the x- and z-directions). In various embodiments, TT voltages may be applied to the TT electrodes 116 to generate a time-dependent electric potential field that causes the objects of the group of objects to traverse corresponding trajectories to perform a deterministic reshaping and/or reordering function. In various embodiments, the number of sequences of TT electrodes 114 may, in combination, be biased, with TT voltages that contribute to a variable combined electrical and/or magnetic field to trap at least one atomic object (e.g., ion) in a potential well above at least one of either an upper surface of the sequences of TT electrodes 114 and/or the RF rails 112. For example, the electrical and/or magnetic field generated at least in part by voltages applied to the TT electrodes of the sequences of TT electrodes 114 may trap at least one atomic object in a potential well above the upper surface of the second sequence of TT electrodes 114B and/or the longitudinal gap 105. Additionally, the TT voltages applied to the electrodes 116 may cause ions trapped within the potential well above the upper surface of the second sequence of TT electrodes 114B and/or the longitudinal gap 105 to traverse trajectories corresponding to various functions of the ion trap.

Depending on factors such as the charge on the at least one atomic object and/or the shape and/or magnitude of the combined electrical and/or magnetic fields, the at least one atomic object can be stabilized at a particular distance (e.g., approximately 20 μm to approximately 200 μm) above an upper surface of the ion trap 100 (e.g., the coplanar upper surface of the sequences of TT electrodes 114 and RF rails 112). To further contribute to controlling the transit of atomic objects along desired trajectories, the ion trap 100 may be operated within a cryogenic and/or vacuum chamber capable of cooling the ion trap to a temperature of less than 124 Kelvin (e.g., less than 100 Kelvin, less than 50 Kelvin, less than 10 Kelvin, less than 5 Kelvin, and/or the like), in various embodiments.

In various embodiments, the RF rails 112, the sequences of electrodes 114, and/or the confinement potential generated by the RF rails and/or the sequences of electrodes 114 define a confinement plane 103 of the ion trap. In various embodiments, the RF rails 112, the sequences of electrodes 114, and/or the confinement potential generated by the RF rails and/or the sequences of electrodes 114 define an axis 101 of the ion trap.

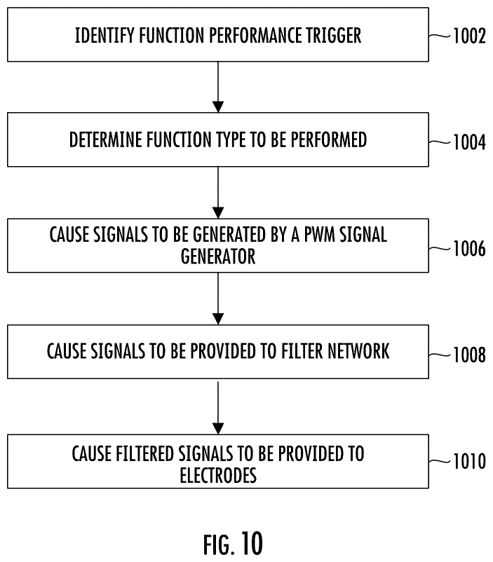

In various embodiments, the TT voltages applied to the TT electrodes 116 are controlled by one or more connected devices (e.g., a controller 30 as shown in FIG. 10 and/or the like) via leads. For example, depending on the positive or negative charge on the at least one atomic object, TT voltages may be raised or lowered for TT electrodes 116 in the vicinity of a particular ion to cause the particular ion to traverse a desired trajectory. For example, a controller 30 may control a voltage driver to cause the voltage driver to apply TT voltages to the TT electrodes to generate a time-dependent electric potential (e.g., an electric potential that evolves with time) that causes various functions of the ion trap to be performed (e.g., transporting atomic objects from one location within the ion trap to another location in the ion trap, maintaining an atomic object in a particular location within the ion trap so that quantum logic gate may be performed on the atomic object, causing two atomic objects to swap positions within the ion trap, cause two atomic objects to move close together, cause two atomic objects that are close together to move apart from one another, and/or the like). In various embodiments, the voltage driver is in electrical communication with a TT electrode 116 via a filter (e.g., network of filters). For example, the filter may be controlled (e.g., by a filter driver) to shape the noise in the signal applied to the TT electrodes 116 based on a function to be performed by/in the ion trap via the potential generated by the application of the signal to the TT electrodes

### Exemplary PWM Control System

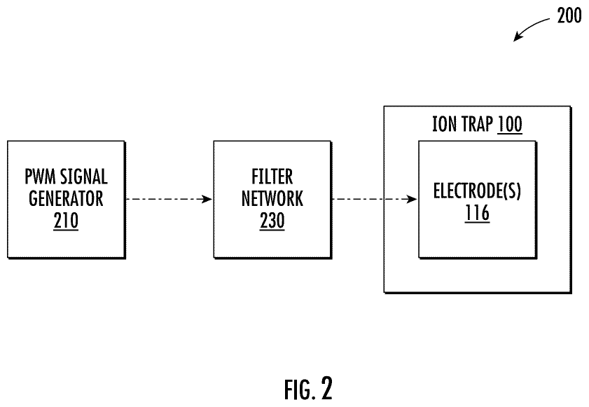

FIG. 2 illustrates an exemplary PWM control system 200, in accordance with an example embodiment. In various embodiments, a controller 30 may control one or more PWM signal generators 210 (e.g., voltage sources 50 shown in FIG. 10) to cause signals to be applied to electrical components (e.g., electrodes 116) of a system configured to perform multiple functions that have differing tolerances and/or requirements. In some embodiments, the PWM control system 200 may be provided for each electrode 116. In some other embodiments, the PWM control system 200 may provide a signal to multiple electrodes 116 of an ion trap. In various embodiments, the PWM control system 200 incorporates or otherwise embodies a noise mitigation circuitry configured to shape and/or condition a signal (e.g., a signal generated by a PWM signal generator) applied to one or more electrodes 116 of the ion trap. As described above, the application of the signals to the electrodes 116 causes a potential field to be generated that may cause one or more functions to be performed on atomic objects captured within an ion trap 100. Different functions have different sensitivities (e.g., noise sensitivities) and therefore different tolerance and/or requirements (e.g., noise requirements). Thus, the PWM control system 200 may be used to shape and/or condition the signal, including mitigating the noise, generated by a PWM signal generator (or other signal generator) and applied to the electrodes 116.

In various embodiments, and as depicted in FIG. 2, the PWM control system 200 comprises a PWM signal generator 210 and a filter network 230. In various embodiments, the output of the PWM signal generator 210 is used to drive the filter network 230. For example, a PWM signal generator 210 may function as a voltage driver. In some embodiments, the controller 30 may control one or more PWM signal generators 210 to cause signals (e.g., voltage signals) to be generated and applied to electrical components (e.g., electrodes 116) of a system configured to perform multiple functions that have differing tolerances and/or requirements. The filter network 230 may receive the signal generated by the PWM signal generator 210 and filter the signal. In some embodiments the filter network 230 may filter the generated signal in accordance with a requirement (e.g., noise requirement) and/or in accordance with an operating response. The filtered signal is then provided to the electrodes 116 so that the resulting potential field may be used to perform a function. Thus, the filtered signal provided to the electrodes 116 can have an appropriate noise profile for the function to be performed via potential field resulting from the application of the signal to the electrodes 116. As another example, in some embodiments, the controller 30 may control one or more PWM signal generators 210 to cause signals (e.g., voltage signals) to be generated and applied to electrical circuitry (e.g., a gain network comprising one or more amplifiers) before being applied to electrical components (e.g., electrodes 116) of a system configured to perform multiple functions that have differing tolerances and/or requirements, as described above.

In various embodiments, a filter network 230 may comprise one or more filters. For example, in some embodiments, a filter network 230 may comprise a single filter (e.g., low-pass filter, high-pass, band-pass, and/or band-stop filters), while in some embodiments, a filter network 230 may comprise multiple (e.g., two or more) filters. In example embodiments with multiple filters, the filters may be of the same or different types (e.g., low-pass filter, high-pass, band-pass, and/or band-stop filters). In some embodiments, a filter of a filter network 230 may be of a singly terminated type with a specific filter response (e.g., a Butterworth, Bessel, Chebyshev, Elliptic, Legrende, and/or the like). Various filters (e.g., having various responses) may be used in various embodiments, and the filters may be active filters and/or passive filters. The filtering by filter network 230 will be to have the signal output from filter network 230 meet the requirements and tolerances of, for example, the electrode(s) 116, which may be a target filter function.

In an example embodiment, and as depicted in FIG. 3, a filter network 300 comprises input end 320 and output end 330. In an example embodiment, the filter network 300 comprises the filtering element passive filter 306. It would be appreciated that in some other embodiments, the filtering element may comprise other types of filtering elements and/or may comprise multiple filtering elements, which may be of the same time or different types. The passive filter 306 may have a desired cut-off frequency. In some embodiments, a passive filter 306 may comprise a passive RC filter, such as a low pass RC filter. As should be understood, a low pass filter passes frequencies lower than the cut-off frequency and does not pass frequencies higher than the cut-off frequency. A high pass filter passes frequencies higher than the cut-off frequency and does not pass frequencies lower than the cut-off frequency. Further, as should be understood, the response of a filter around the cut-off frequency may not be an idealistic step function and may include some roll-over and/or a transition region.

In an example embodiment, the input end 320 receives the signal generated by the PWM signal generator 210. In some embodiments, the signal is then passed to an amplifier 302. The signal, after being amplified by the amplifier 302, is passed to the passive filter 306. The filtered signal is then provided to the electrodes 116 so that the resulting potential field may be used to perform a function. Moreover, the filtered signal provided to the electrodes 116 has an appropriate profile within the required tolerances (e.g., noise tolerance) for the function to be performed via potential field resulting from the application of the signal to the electrodes 116.

In some embodiments, the amplifier 302 may be omitted. In an exemplary embodiment, a signal from PWM signal generator 210 may be generated, which may include a portion of the signal (e.g., harmonic components and/or noise) that will be removed by the filter. In an exemplary embodiment, the filter network may include a first filter (e.g., a passive filter) that may provide noise shaping (e.g., including removal of harmonic component and noise in the signal), and may include a second filter (not shown) that may remove residual noise that may be from the operational amplifiers of the passive filter 306. The design of components comprising the passive filter 306 may include, for example, resistor(s), capacitor(s), and/or other components that minimize noise. In one example, the passive filter 306 may comprise a passive RC filter that includes at least one resistor and at least one capacitor. Thus, the controller 30 may control a PWM signal generator 210 to provide a particular signal. The controller 30 may control a filter network 300 to filter a signal generated by the PWM signal generator 210 in accordance with a requirement (e.g., noise requirement). Additionally or alternatively, in some embodiments, the controller 30 may control a filter network 300 to control the operating response of a filter. For example, in some embodiments, the filter network 300 may receive the signal generated by the PWM signal generator 210 and filter the signal in accordance with a requirement (e.g., noise requirement) and/or in accordance with operating response selected by the controller 30 before providing the resulting filtered signal to the electrodes 116 so that the resulting potential field may be used to perform a function.

In various embodiments, the PWM signal generator 210 may comprise one or more signal sources (e.g., voltage source, current source, arbitrary waveform generator, digital-to-analog converter, and/or the like) and may embody a PWM circuitry (not shown) configured to generate a PWM signal (e.g., a pulse wave) with a variable duty cycle. A PWM signal (e.g., a pulse wave), may describe a non-sinusoidal periodic waveform in which the amplitudes of the waveform alternate at a given frequency between a minimum value (e.g., OFF state) and a maximum value (e.g., ON state). A duty cycle of a PWM signal may describe the ratio of the high period of the PWM signal to the total period of the PWM signal. Further the duty cycle of a PWM signal may determine the DC voltage applied to the electrodes 116. A PWM signal may have a switching frequency that describes how frequent the PWM signal alternates between the ON state and the Off state, and may be determined based on the inverse of the PWM signal period. A PWM signal (e.g., pulse wave) may include DC component and harmonic component (e.g., including noise) at certain frequencies. In embodiments, a PWM signal generator 210 may embody a PWM circuitry configured to generate a PWM signal (e.g., pulse wave) with a variable duty cycle based on the output of a counter, a clock, an arbitrary waveform generator, a combination thereof, and/or the like. For example, in one example, the PWM signal generator 210 may embody a PWM circuitry configured to generate a pulse wave output (e.g., with a variable duty cycle) based on comparing the magnitudes of a triangle (or sawtooth) waveform with a reference signal. In the noted example, the PWM signal generator 210 may include a comparator (not shown) configured for comparing a triangle (or sawtooth) waveform with a reference signal to output a PWM signal (e.g., pulse wave) with a variable duty cycle. It would be appreciated, however, that a PWM signal generator 210 may be embodied in a variety of forms and may include a PWM circuitry configuration of a variety of PWM circuitry configurations. For example, in some embodiments, the PWM signal generator 210 may be embodied as a programmable logic device, such as a field-programmable logic array (FPGA), an application-specific integrated circuit (ASIC), and/or the like. In some embodiments, the PWM signal generator 210 may be configured to generate a pulse wave (e.g., with a variable duty cycle) based on the output of one or more clocks of a programmable logic device. In one example, the PWM signal generator 210 may comprise a PWM counter and/or a clock configured for generating a pulse wave with a variable duty cycle. The PWM counter, for example, may comprise an N-bit free running counter at a defined frequency based at least in part on associated clock. In example embodiments, the PWM counter may comprise an 8-bit free running counter, a 16-bit free running counter, and/or the like that may be continuously incremented up to a maximum value in accordance with associated clock speed.

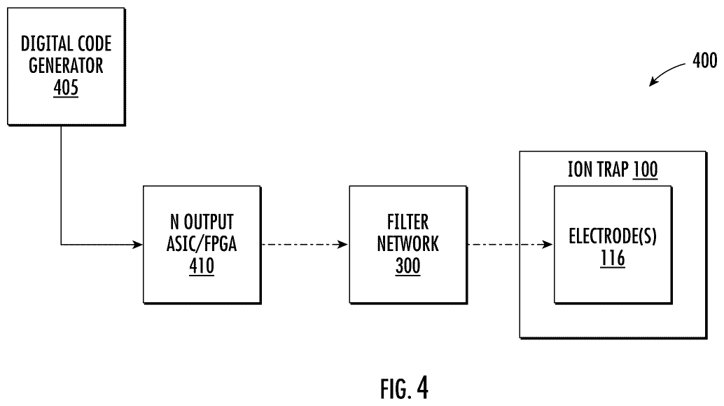

In an exemplary embodiments, and as depicted in FIG. 4, a PWM signal generator 400 is embodied as or embodies an FPGA 410 or ASIC (e.g., FPGA-based PWM signal generator 410) and includes a digital code generator 405 configured for providing input data (e.g., clock length, duty cycle, and/or the like) to the FPGA 410 (or ASIC), for example, via a digital serial bus. An exemplary FPGA 410 may include a PWM counter and a clock cycle counter, wherein the PWM counter (e.g., N-bit free running counter) may be incremented based on the clock cycle counter (e.g., the PWM counter may increment when the clock cycle counter is 0 and back to zero when the max value is reached). The PWM output may be determined based on comparing the PWM counter value to the duty cycle input data. For example, the FPGA-based PWM signal generator 410 may output “1” (e.g., ON state) when the PWM counter value is larger than the duty cycle input value and output a “0” (e.g., OFF state) when the PWM counter value is less than the duty cycle input value. An exemplary PWM signal generator may incorporate a noise mitigation circuitry and/or configured such that noise and/or harmonic components in the signal generated by the PWM signal generator is removed (or suppressed), or otherwise facilitates removal (or suppression) of harmonic components and/or noise in the signal generated by the PWM signal generator.

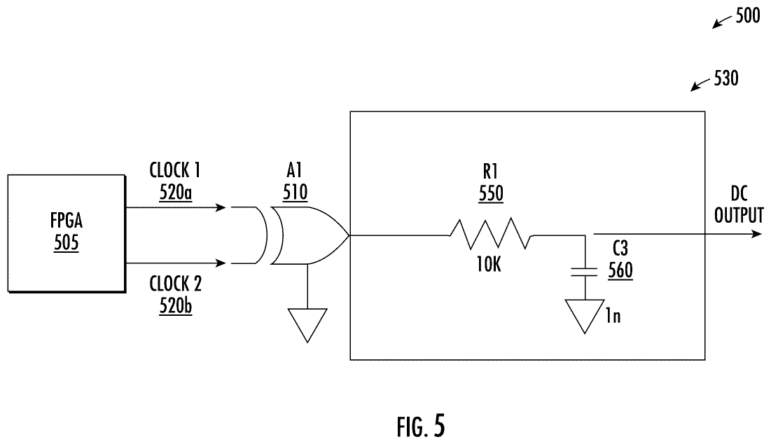

FIG. 5, illustrates a schematic of an example PWM signal generator 500 embodying a noise mitigation circuitry. In an example embodiment, and as depicted in FIG. 5, the PWM signal generator 500 may be an FPGA-based PWM signal generator, and may be configured to generate a high frequency PWM signal output such that harmonic and/or noise (e.g., noise spur) in the signal generated by the PWM signal generator 500 are at frequencies that are not required by the quantum computer and/or are at frequencies that an atomic object, such as an ion, is insensitive to. Moreover, the generated high frequency PWM signal output may facilitate effective and efficient removal or suppression (e.g., by filter network 530) of the corresponding high frequency harmonic component and/or noise in the PWM signal output. Thus, retaining the desired DC component (e.g., DC voltage) of the PWM signal output, which in turn is applied to one or more electrodes 116 of the ion trap. The depicted filter network 530 may be similar to filter network 300 discussed above in connection with FIG. 3.

According to various embodiments, of the present disclosure, a high frequency PWM signal output (e.g., PWM signal output with high switching frequency) may be achieved using one or more of a variety of techniques. For example, a programmable logic device, such as an FPGA generally comprises programmable logic blocks, such as AND gates, OR gates, XOR gates, and/or the like, each of which may be used to perform logical operations individually or as a combination. In various embodiments, one or more of the noted programmable logic blocks may be employed to generate a high frequency PWM signal output. In an example embodiment, and as depicted in FIG. 5, the PWM signal generator (e.g., embodying an FPGA 505) may include an XOR gate 510 and two clocks 520a and 520b whose signals are provided as input to the XOR gate and configured for establishing (e.g., setting) the pulse width of the PWM signal output. A first clock of the two clocks may be associated with a delay (e.g., a configurable delay) relative to a second clock of the two clocks (e.g., the first clock may be delayed relative to the second clock). The controller 30, for example, may cause the XOR gate to perform XOR operation based on the delayed first clock signal input and the second clock signal input, to output a PWM signal output having increased switching frequency (e.g., high frequency PWM signal output). Thus, the PWM signal generator 500 may be configured to generate a high frequency PWM signal output based at least in part on a first clock signal and a second clock signal, with the first clock signal having a configurable delay (e.g., adjustable delay) relative to the second clock signal. For example, a high frequency PWM signal may be generated based at least in part on a switching frequency that is generated using the XOR gate, wherein the XOR gate is configured to perform an XOR operation on a first clock signal generated by the first clock and a second clock signal generated by the second clock.

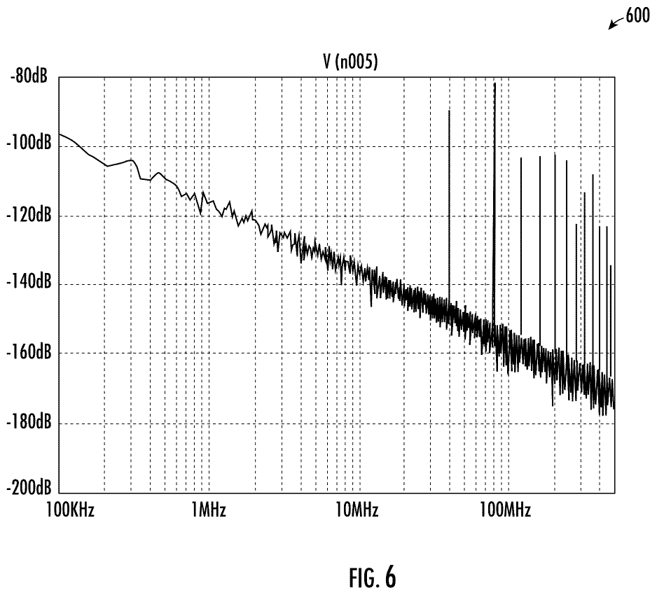

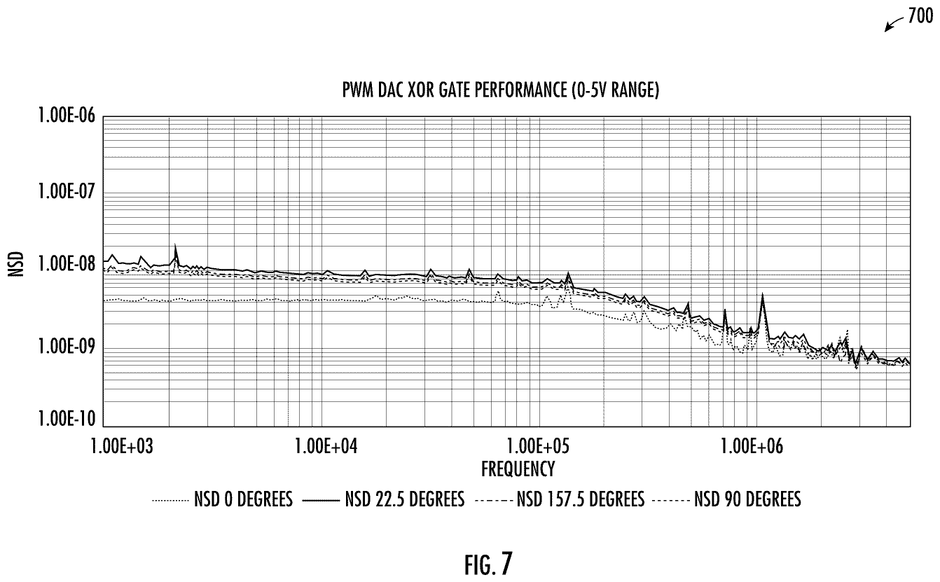

As shown in FIG. 5, the generated high frequency PWM signal output may then be provided as input to a filter network 530 to generate a desired signal (e.g., voltage signal) that can be applied to electrical components (e.g., electrodes) of the ion trap. As shown in FIG. 5, the filter network 530 may comprise a passive RC filter comprising at least one resistor 550 and at least one capacitor 560. FIG. 6 illustrates a Fast Fourier Transform (FFT) plot for a 10 bit PWM code running at 40 MHz frequency and filtered by a single pole 16 kHz RC filter in accordance with the illustrated embodiment of FIG. 5. Further, FIG. 7 provides a noise spectral density (NSD) plot for an exemplary PWM signal generator 500 in accordance with the illustrated embodiment of FIG. 5.

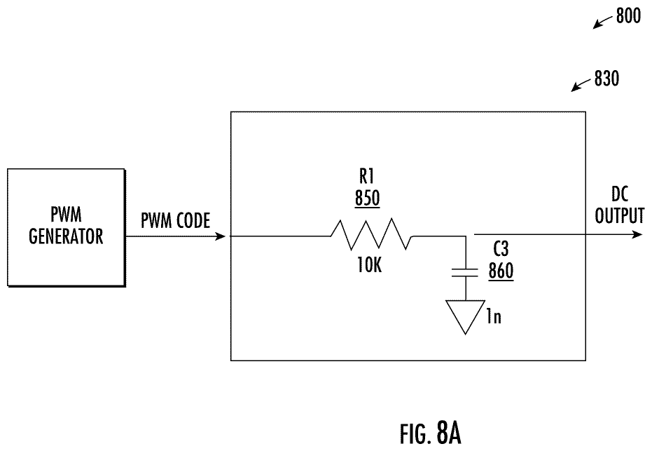

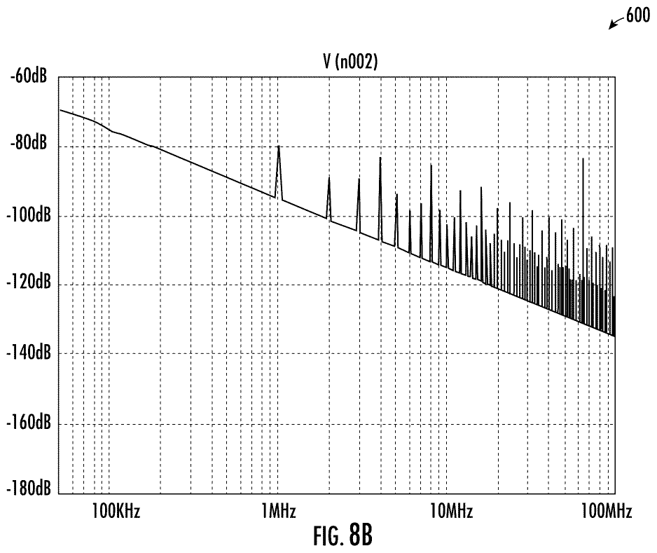

FIG. 8a, illustrates a schematic of another example PWM signal generator 800 embodying an exemplary noise mitigation circuitry. In the depicted embodiment of FIG. 8a, the switching frequency of the signal generated by the PWM signal generator 800 is selected such the lower harmonics frequency is suppressed (e.g., selecting a modulation code such that a substantial amount of glitch energy of the signal generated by the PWM signal generator 800 is at high order harmonics). For example, the clock frequency may be selected such that spurs (e.g., noise spurs) do not disturb ion motional modes.

As shown in FIG. 8a, the generated high frequency PWM signal output (e.g., PWM code) may then be provided as input to a filter network 830 to generate a desired signal (e.g., voltage signal) that can be applied to electrical components (e.g., electrodes) of the ion trap. As shown in FIG. 8a, the filter network 830 may comprise a passive RC filter comprising at least one resistor 850 and at least one capacitor 860. FIG. 8b illustrates a FFT plot for an 8 bit PWM code running at 1 MHz frequency and filtered by a single pole 16 kHz RC filter in accordance with the illustrated embodiment of FIG. 8a. In some other embodiments, dithering or frequency modulation may be used to spread out glitch energy at certain frequencies.

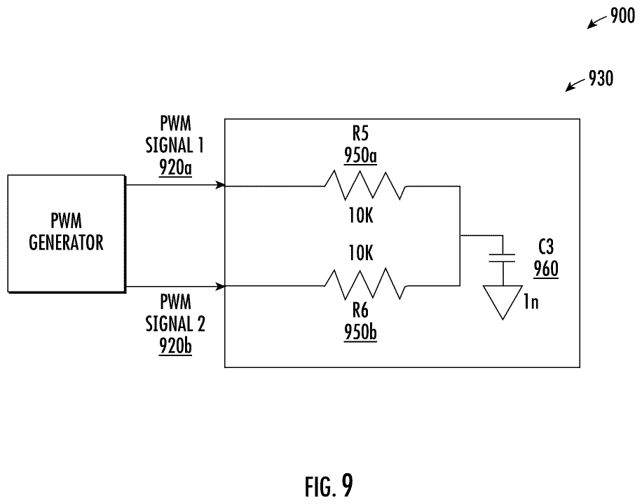

FIG. 9, illustrates a schematic of yet another example PWM signal generator 900 embodying a noise mitigation circuitry. In an example embodiment, and as depicted in FIG. 9, harmonic component of the generated PWM signal may be suppressed based on combining a first PWM signal output 920a and a second PWM signal output 920b (e.g., the noise mitigation circuitry may comprise a circuit that combines two PWM signal outputs, such as first PWM signal output 920a and second PWM signal output 920b). The second PWM signal output may be associated with a delay. In some embodiments, the delay may correspond to half the harmonic period in the signal generated by the PWM signal generator 900. In embodiments, the signal generated based on combining the first PWM signal output 920a and the second PWM signal output 920b is then provided as input to a filter network 930. As shown in FIG. 9, the filter network may comprise an RC filter comprising at a first resistor 950a configured to receive the first PWM signal output 920a and at least a second resistor 950b configured to receive the second PWM signal output 920b. The filter network 930 may include at least one capacitor 960 coupled to the first and second resistors 950a and 950b. In some embodiments, the first PWM signal output 920a may control the coarse resolution and the second PWM signal output 920b may control the fine resolution. Additionally or alternatively, in the illustrated embodiment of FIG. 9, the resolution may be determined based at least in part on the value of resistor 950b. For example, a higher resolution can be achieved by increasing the value of resistor 950b.

FIG. 10 provides a flowchart illustrating example processes, procedures, operations, and/or the like that may be performed by a controller 30, for example, to cause a PWM signal (that account for harmonics and noise in the signal) to be provided to an electrical component (e.g., electrodes 116). For the sake of clarity, the illustrated example focuses on the application of a PWM signal with a single electrode 116. However, as should be understood, a system may comprise a plurality of PWM signal generators 210 and a plurality of filter networks 230, such that PWM signals with removed and/or suppressed harmonics may be provided to a plurality of electrodes 116 and/or other electrical components.

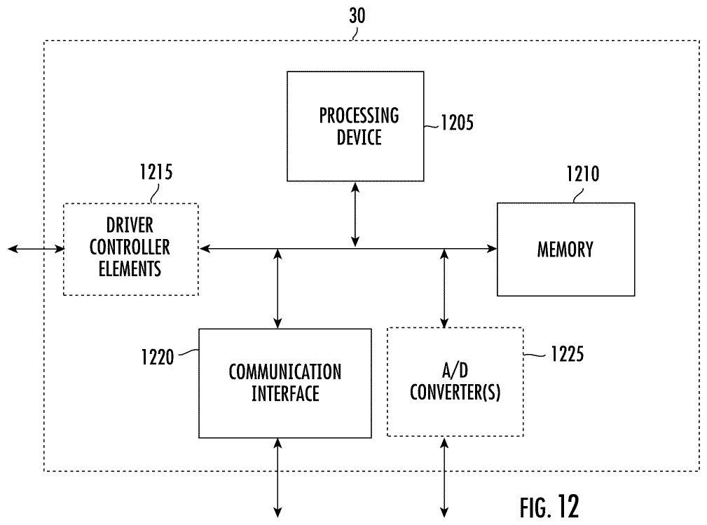

Starting at step/operation 1002, a function performance trigger may be identified. For example, the controller 30 (e.g., using processing device 1205 shown in FIG. 12) may read a next command from a command queue. For example, the command may indicate that a particular set of voltages should be applied to a set of electrodes 116 to perform a particular function. The reading of the command may cause the controller 30 to identify a function performance trigger.

At step/operation 1004, the function to be performed is determined. For example, based on the command and/or the function performance trigger, the controller 30 (e.g., using processing device 1205, memory 1210, and/or the like) may determine the function to be performed. For example, as described above, the function may be transporting atomic objects from one location within the ion trap to another location in the ion trap, maintaining an atomic object in a particular location within the ion trap so that quantum logic gate may be performed on the atomic object, causing two atomic objects to swap positions within the ion trap, causing two atomic objects to move close together, causing two atomic objects that are close together move apart from one another, and/or the like, in an example embodiment. In some embodiments, based on the determined function, a corresponding response of a filter may be identified. For example, the ion trap 100 may include 300 TT electrodes 116. Each TT electrode 116 may be associated with a PWM signal generator 210 and a filter network 230, such that the signal applied to each individual TT electrode 116 may be individually tailored.

At step/operation 1006, the controller 30 causes the PWM signal generator(s) 210 corresponding to the set of electrodes to generate signals in accordance with the command.

At step/operation 1008, the controller 30 causes the PWM signal generator(s) 210 to provide the generated signals to the filter network(s) 230. The filter network(s) 230 filters the signals in accordance with a noise requirement and/or in accordance with the selected operating response (e.g., the response that corresponds to the determined function). The harmonics and the noise of the signals is thus shaped in accordance with the function the signal will cause the system to perform.

At step/operation 1010, the controller 30 causes the filtered signal to be applied to the corresponding electrode such that the function is performed.

In various embodiments, the process then returns to step/operation 1102 and another command is read corresponding to another function. The operating response of the filter network may be adjusted and/or switched accordingly so that the next signal is filtered, by the filter, using an operating response that corresponds to the function that next signal will cause the system to perform. As such, the process shown in FIG. 10 may be repeated as required for the controller 30 to cause the system to perform the desired functions.

### Technical Advantages

Various embodiments provide technical solutions to the technical problem of generating and providing signals to a system that cause the system to perform different functions, wherein the different functions have different tolerances or requirements. For example, in the example system of the trapped ion quantum computer described above, when performing the transport function, performance of the function may be sensitive to noise at frequencies around 1 MHz and when performing the maintaining function (e.g., maintaining the atomic object at a particular location within the ion trap so that a quantum logic gate may be executed on the atomic object), performance of the function may be sensitive to noise at frequencies around 250 kHz. Current methods for noise shaping of the signals includes filtering all of the signals based on the noise tolerances of the function having the most stringent noise tolerances. However, in the described example, performing the transport function using the noise requirements configured to optimize performance of the maintaining function, leads to decreased performance of the transport function. For example, performing the transport function using the noise requirements configured to optimize performance of the maintaining function decreases the speed and/or bandwidth with which the transport function may be performed. Example embodiments provide technical solutions to these technical problems by providing PWM signals (embodying noise mitigation circuitry and/or techniques) that meet noise requirements and tolerances required for multiple functions. Thus, example embodiments provide technical solutions that lead to improved system performance. For example, in some embodiments, to meet the noise requirements of electrical components (such as electrodes), a PWM signal generator may be embodied as or embody a programmable logic device (e.g., FPGA, ASIC, and/or the like) that requires less computational resources to generate a PWM signal. By doing so, example embodiments of the present disclosure provide technical solutions that leads to improved system performance based at least in part on less computational requirements.

### Exemplary Quantum Computer Comprising an Ion Trap Apparatus

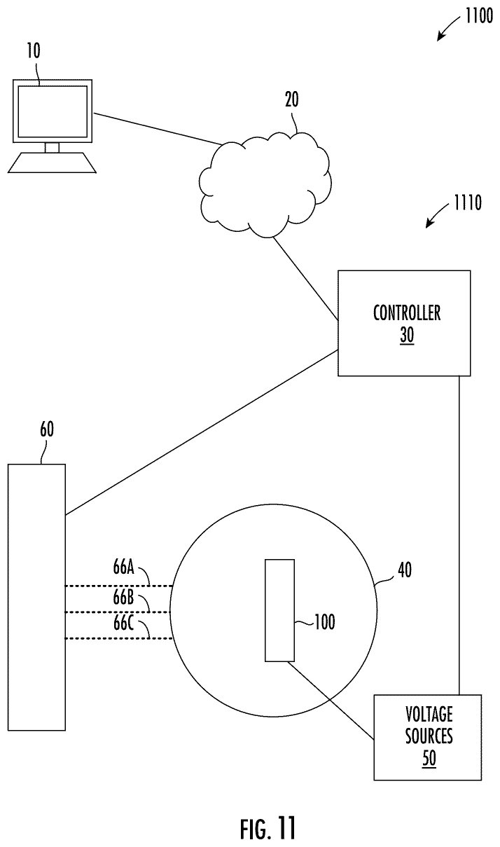

As described above, the PWM control system (e.g., comprising PWM signal generator and the filter network) may be part of a quantum computer 1110. For example, PWM control system 200 may be used to provide a signal and shape the noise of signals being applied to electrodes 116 of an ion trap that traps atomic objects used as the qubits of the quantum computer 1110. FIG. 11 provides a schematic diagram of an example quantum computer system 1100 comprising a confinement apparatus (e.g., ion trap 100), in accordance with an example embodiment. In various embodiments, the quantum computer system 1100 comprises a computing entity 10 and a quantum computer 1110. In various embodiments, the quantum computer 1110 comprises a controller 30, a cryostat and/or vacuum chamber 40 enclosing a confinement apparatus (e.g., ion trap 100), and one or more manipulation sources 60. In an example embodiment, the one or more manipulation sources 60 may comprise one or more lasers (e.g., optical lasers, microwave sources, and/or the like). Beams, pulses, fields, and/or the like generated by the manipulation sources 60 may be provided to the ion trap 100 via one or more optical paths 66 (e.g., 66A, 66B, 66C) in an example embodiment. In various embodiments, the one or more manipulation sources 60 are configured to manipulate and/or cause a controlled quantum state evolution of one or more atomic objects within the confinement apparatus. For example, in an example embodiment, wherein the one or more manipulation sources 60 comprise one or more lasers, the lasers may provide one or more laser beams to the confinement apparatus within the cryogenic and/or vacuum chamber 40. In various embodiments, the quantum computer 1110 comprises one or more voltage sources 50. For example, the voltage sources 50 may comprise a plurality of TT voltage drivers and/or voltage sources and/or at least one RF driver and/or voltage source. For example, the voltage sources 50 may comprise one or more PWM signal generators 210. The voltage sources 50 may be electrically coupled to the corresponding potential generating elements (e.g., TT electrodes 116) of the confinement apparatus (e.g., ion trap 100) via a filter network 230, in an example embodiment.

In various embodiments, a computing entity 10 is configured to allow a user to provide input to the quantum computer 1110 (e.g., via a user interface of the computing entity 10) and receive, view, and/or the like output from the quantum computer 1110. The computing entity 10 may be in communication with the controller 30 of the quantum computer 1110 via one or more wired or wireless networks 1320 and/or via direct wired and/or wireless communications. In an example embodiment, the computing entity 10 may translate, configure, format, and/or the like information/data, quantum computing algorithms, and/or the like into a computing language, executable instructions, command sets, and/or the like that the controller 30 can understand and/or implement.

In various embodiments, the controller 30 is configured to control the voltage sources 50, cryogenic system and/or vacuum system controlling the temperature and pressure within the cryogenic and/or vacuum chamber 40, manipulation sources 60, and/or other systems controlling various environmental conditions (e.g., temperature, pressure, and/or the like) within the cryogenic and/or vacuum chamber 40 and/or configured to manipulate and/or cause a controlled evolution of quantum states of one or more atomic objects within the confinement apparatus. For example, the controller 30 may cause a controlled evolution of quantum states of one or more atomic objects within the confinement apparatus to execute a quantum circuit and/or algorithm. In various embodiments, the atomic objects confined within the confinement apparatus are used as qubits of the quantum computer 1110.

### Exemplary Controller

In various embodiments, a confinement apparatus is incorporated into a quantum computer 1110. In various embodiments, a quantum computer 1110 further comprises a controller 30 configured to control various elements of the quantum computer 1110. For example, the controller 30 may be configured to control the voltage sources 50, a cryogenic system and/or vacuum system controlling the temperature and pressure within the cryogenic and/or vacuum chamber 40, manipulation sources 60, and/or other systems controlling the environmental conditions (e.g., temperature, humidity, pressure, and/or the like) within the cryogenic and/or vacuum chamber 40 and/or configured to manipulate and/or cause a controlled evolution of quantum states of one or more atomic objects within the confinement apparatus.

As shown in FIG. 12, in various embodiments, the controller 30 may comprise various controller elements including processing elements 1205, memory 1210, driver controller elements 1215, a communication interface 1220, analog-digital converter elements 1225, and/or the like. For example, the processing elements 1205 may comprise programmable logic devices (PLDs), complex PLDs (CPLDs), microprocessors, coprocessing entities, application-specific instruction-set processors (ASIPs), integrated circuits, application specific integrated circuits (ASICs), field programmable gate arrays (FPGAs), programmable logic arrays (PLAs), hardware accelerators, other processing devices and/or circuitry, and/or the like. and/or controllers. The term circuitry may refer to an entirely hardware embodiment or a combination of hardware and computer program products. In an example embodiment, the processing element 1205 of the controller 30 comprises a clock and/or is in communication with a clock.

For example, the memory 1210 may comprise non-transitory memory such as volatile and/or non-volatile memory storage such as one or more of as hard disks, ROM, PROM, EPROM, EEPROM, flash memory, MMCs, SD memory cards, Memory Sticks, CBRAM, PRAM, FeRAM, RRAM, SONOS, racetrack memory, RAM, DRAM, SRAM, FPM DRAM, EDO DRAM, SDRAM, DDR SDRAM, DDR2 SDRAM, DDR3 SDRAM, RDRAM, RIMM, DIMM, SIMM, VRAM, cache memory, register memory, and/or the like. In various embodiments, the memory 1210 may store qubit records corresponding the qubits of quantum computer (e.g., in a qubit record data store, qubit record database, qubit record table, and/or the like), a calibration table, an executable queue, computer program code (e.g., in a one or more computer languages, specialized controller language(s), and/or the like), and/or the like. In an example embodiment, execution of at least a portion of the computer program code stored in the memory 1210 (e.g., by a processing element 1205) causes the controller 30 to perform one or more steps, operations, processes, procedures and/or the like described herein for applying signals with dynamically shaped noise to electrodes of the ion trap 100 for performance of a function that corresponds to the dynamically shaped noise.

In various embodiments, the driver controller elements 1215 may include one or more drivers and/or controller elements each configured to control one or more drivers. In various embodiments, the driver controller elements 1215 may comprise drivers and/or driver controllers. For example, the driver controllers may be configured to cause one or more corresponding drivers to be operated in accordance with executable instructions, commands, and/or the like scheduled and executed by the controller 30 (e.g., by the processing element 1205). In various embodiments, the driver controller elements 1215 may enable the controller 30 to operate a manipulation source 60. In various embodiments, the drivers may be laser drivers; vacuum component drivers; drivers for controlling the flow of current and/or voltage applied to TT, RF, (e.g., voltage sources 50), and/or other electrodes used for maintaining and/or controlling the ion trapping potential of the ion trap 100 (and/or other driver for providing driver action sequences to potential generating elements of the confinement apparatus); drivers for controlling the operating response of one or more filters; cryogenic and/or vacuum system component drivers; and/or the like. For example, the drivers may control and/or comprise TT and/or RF voltage drivers and/or voltage sources that provide voltages and/or electrical signals to the TT electrodes 116 and/or RF rails 112. In various embodiments, the controller 30 comprises means for communicating and/or receiving signals from one or more optical receiver components such as cameras, MEMs cameras, CCD cameras, photodiodes, photomultiplier tubes, and/or the like. For example, the controller 30 may comprise one or more analog-digital converter elements 1225 configured to receive signals from one or more optical receiver components, calibration sensors, and/or the like.

In various embodiments, the controller 30 may comprise a communication interface 1220 for interfacing and/or communicating with a computing entity 10. For example, the controller 30 may comprise a communication interface 1220 for receiving executable instructions, command sets, and/or the like from the computing entity 10 and providing output received from the quantum computer 1110 (e.g., from an optical collection system) and/or the result of a processing the output to the computing entity 10. In various embodiments, the computing entity 10 and the controller 30 may communicate via a direct wired and/or wireless connection and/or one or more wired and/or wireless networks 1320.

### Exemplary Computing Entity

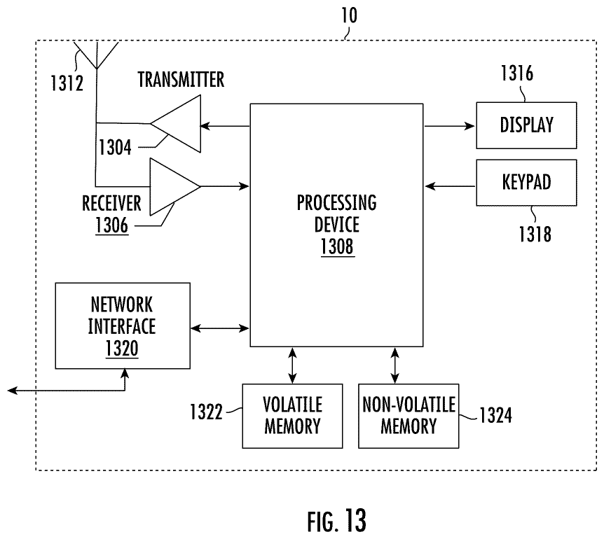

FIG. 13 provides an illustrative schematic representative of an example computing entity 10 that can be used in conjunction with embodiments of the present invention. In various embodiments, a computing entity 10 is configured to allow a user to provide input to the quantum computer 1110 (e.g., via a user interface of the computing entity 10) and receive, display, analyze, and/or the like output from the quantum computer 1110.

As shown in FIG. 13, a computing entity 10 can include an antenna 1312, a transmitter 1304 (e.g., radio), a receiver 1306 (e.g., radio), and a processing element 1308 that provides signals to and receives signals from the transmitter 1304 and receiver 1306, respectively. The signals provided to and received from the transmitter 1304 and the receiver 1306, respectively, may include signaling information/data in accordance with an air interface standard of applicable wireless systems to communicate with various entities, such as a controller 30, other computing entities 10, and/or the like. In this regard, the computing entity 10 may be capable of operating with one or more air interface standards, communication protocols, modulation types, and access types. For example, the computing entity 10 may be configured to receive and/or provide communications using a wired data transmission protocol, such as fiber distributed data interface (FDDI), digital subscriber line (DSL), Ethernet, asynchronous transfer mode (ATM), frame relay, data over cable service interface specification (DOCSIS), or any other wired transmission protocol. Similarly, the computing entity 10 may be configured to communicate via wireless external communication networks using any of a variety of protocols, such as general packet radio service (GPRS), Universal Mobile Telecommunications System (UMTS), Code Division Multiple Access 2000 (CDMA2000), CDMA2000 1X (1xRTT), Wideband Code Division Multiple Access (WCDMA), Global System for Mobile Communications (GSM), Enhanced Data rates for GSM Evolution (EDGE), Time Division-Synchronous Code Division Multiple Access (TD-SCDMA), Long Term Evolution (LTE), Evolved Universal Terrestrial Radio Access Network (E-UTRAN), Evolution-Data Optimized (EVDO), High Speed Packet Access (HSPA), High-Speed Downlink Packet Access (HSDPA), IEEE 802.11 (Wi-Fi), Wi-Fi Direct, 802.16 (WiMAX), ultra wideband (UWB), infrared (IR) protocols, near field communication (NFC) protocols, Wibree, Bluetooth protocols, wireless universal serial bus (USB) protocols, and/or any other wireless protocol. The computing entity 10 may use such protocols and standards to communicate using Border Gateway Protocol (BGP), Dynamic Host Configuration Protocol (DHCP), Domain Name System (DNS), File Transfer Protocol (FTP), Hypertext Transfer Protocol (HTTP), HTTP over TLS/SSL/Secure, Internet Message Access Protocol (IMAP), Network Time Protocol (NTP), Simple Mail Transfer Protocol (SMTP), Telnet, Transport Layer Security (TLS), Secure Sockets Layer (SSL), Internet Protocol (IP), Transmission Control Protocol (TCP), User Datagram Protocol (UDP), Datagram Congestion Control Protocol (DCCP), Stream Control Transmission Protocol (SCTP), HyperText Markup Language (HTML), and/or the like.

Via these communication standards and protocols, the computing entity 10 can communicate with various other entities using concepts such as Unstructured Supplementary Service information/data (USSD), Short Message Service (SMS), Multimedia Messaging Service (MMS), Dual-Tone Multi-Frequency Signaling (DTMF), and/or Subscriber Identity Module Dialer (SIM dialer). The computing entity 10 can also download changes, add-ons, and updates, for instance, to its firmware, software (e.g., including executable instructions, applications, program modules), and operating system.

The computing entity 10 may also comprise a user interface device comprising one or more user input/output interfaces (e.g., a display 1316 and/or speaker/speaker driver coupled to a processing element 1308 and a touch screen, keyboard, mouse, and/or microphone coupled to a processing element 1308). For instance, the user output interface may be configured to provide an application, browser, user interface, interface, dashboard, screen, webpage, page, and/or similar words used herein interchangeably executing on and/or accessible via the computing entity 10 to cause display or audible presentation of information/data and for interaction therewith via one or more user input interfaces. The user input interface can comprise any of a number of devices allowing the computing entity 10 to receive data, such as a keypad 1318 (hard or soft), a touch display, voice/speech or motion interfaces, scanners, readers, or other input device. In embodiments including a keypad 1318, the keypad 1318 can include (or cause display of) the conventional numeric (0-9) and related keys (#, *), and other keys used for operating the computing entity 10 and may include a full set of alphabetic keys or set of keys that may be activated to provide a full set of alphanumeric keys. In addition to providing input, the user input interface can be used, for example, to activate or deactivate certain functions, such as screen savers and/or sleep modes. Through such inputs the computing entity 10 can collect information/data, user interaction/input, and/or the like.

The computing entity 10 can also include volatile storage or memory 1322 and/or non-volatile storage or memory 1324, which can be embedded and/or may be removable. For instance, the non-volatile memory may be ROM, PROM, EPROM, EEPROM, flash memory, MMCs, SD memory cards, Memory Sticks, CBRAM, PRAM, FeRAM, RRAM, SONOS, racetrack memory, and/or the like. The volatile memory may be RAM, DRAM, SRAM, FPM DRAM, EDO DRAM, SDRAM, DDR SDRAM, DDR2 SDRAM, DDR3 SDRAM, RDRAM, RIMM, DIMM, SIMM, VRAM, cache memory, register memory, and/or the like. The volatile and non-volatile storage or memory can store databases, database instances, database management system entities, data, applications, programs, program modules, scripts, source code, object code, byte code, compiled code, interpreted code, machine code, executable instructions, and/or the like to implement the functions of the computing entity 10.

### Conclusion

Many modifications and other embodiments of the invention set forth herein will come to mind to one skilled in the art to which the invention pertains having the benefit of the teachings presented in the foregoing descriptions and the associated drawings. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation.

1. A system for providing a signal to an electrical component, the system comprising:
a PWM signal generator configured to generate at least one signal;
a filter network configured to filter the at least one signal; and
a controller configured to control operation of the PWM signal generator and the filter network,
wherein the controller causes the PWM signal generator to generate the at least one signal, the at least one signal is provided to the filter network, the controller causes the filter network to filter the at least one signal in accordance with a noise requirement, and the filtered at least one signal is provided to an electrical component of the system.

2. The system of claim 1, wherein the PWM signal generator is an FPGA-based PWM signal generator.

3. The system of claim 1, wherein the at least one signal is a high frequency PWM signal.

4. The system of claim 3, wherein the PWM signal generator comprises a first clock, a second clock, and an XOR gate, and wherein the first clock is associated with a delay relative to the second clock.

5. The system of claim 4, wherein the high frequency PWM signal is generated based at least in part on a switching frequency that is generated using the XOR gate, wherein the XOR gate is configured to perform an XOR operation on a first clock signal generated by the first clock and a second clock signal generated by the second clock.

6. The system of claim 1, wherein a first signal generated by the PWM signal generator and a second signal generated by the PWM signal generator are combined to generate a PWM signal having suppressed harmonic component.

7. The system of claim 1, wherein a low harmonic frequency in the at least one signal is suppressed based at least in part on a switching frequency of the at least one signal.

8. The system of claim 1, wherein the filter network comprises a passive filter.

9. The system of claim 1, wherein the system is a quantum computer.

10. The system of claim 9, wherein the electrical component is an electrode of an ion trap having a plurality of ions trapped therein, at least some of the plurality of ions being used as qubits of the quantum computer.

11. A method for providing a signal to an electrical component of a system, the method comprising:
causing, by a controller of the system, a PWM signal generator to generate at least one signal; and
causing, by the controller of the system, a filter network to filter the at least one signal, wherein the at least one signal generated by the PWM signal generator is provided to the filter network, the filter network filters the at least one signal in accordance with a noise requirement, and the filtered at least one signal is provided to an electrical component of the system.

12. The method of claim 11, wherein the PWM signal generator is an FPGA-based PWM signal generator.

13. The method of claim 11, wherein the at least one signal is a high frequency PWM signal.

14. The method of claim 13, wherein the PWM signal generator comprises a first clock, a second clock, and an XOR gate, and wherein the first clock is associated with a delay relative to the second clock.

15. The method of claim 14, wherein the high frequency PWM signal is generated based at least in part on a switching frequency that is generated using the XOR gate, wherein the XOR gate is configured to perform an XOR operation on a first clock signal generated by the first clock and a second clock signal generated by the second clock.

16. The method of claim 11, wherein first signal generated by the PWM signal generator and a second signal generated by the PWM signal generator are combined to generate a PWM signal having suppressed harmonic component.

17. The method of claim 11, wherein low frequency harmonic component of the at least one signal is suppressed based at least in part on selected switching frequency of the at least one signal.

18. The method of claim 11, wherein the filter network comprises a passive filter.

19. The method of claim 11, wherein the system is a quantum computer.

20. A computer program product, the computer program product comprising a non-transitory, machine-readable storage medium storing executable instructions that, when executed with a processor of a controller, cause the controller to:
cause a PWM signal generator to generate at least one signal; and
cause a filter network to filter the at least one signal, wherein
the at least one signal generated by the PWM signal generator is provided to the filter network, the filter network filters the at least one signal in accordance with a noise requirement, and the filtered at least one signal is provided to an electrical component of the system.
